(19) United States
(12) Patent Application Publication
(10) Pub. No.: US 2026/0033016 A1
(43) Pub. Date: Jan. 29, 2026

(54) PHOTOVOLTAIC CELLS IN STRUCTURAL COMPOSITE AUTOMOTIVE PANELS

(71) Applicant: GM Global Technology Operations LLC, Detroit, MI (US)

(72) Inventors: Bradley Allen Newcomb, Troy, MI (US); Selina Xinyue Zhao, Rochester Hills, MI (US); Venkateshwar R. Aitharaju, Troy, MI (US); Bhavesh Shah, Troy, MI (US); Julien P. Mourou, Bloomfield Hills, MI (US); Christopher G. Basela, Ortonville, MI (US)

(21) Appl. No.: 18/785,115

(22) Filed: Jul. 26, 2024

(51) Int. Cl. H10F 19/80; B32B 7/09; B32B 9/04; B32B 17/06; B32B 27/30; B32B 27/36; B60R 16/03; B62D 25/06; H02S 20/30

(52) U.S. Cl. CPC H10F 19/804; B32B 7/09; B32B 9/045; B32B 17/06; B32B 27/308; B32B 27/365; B60R 16/03; B62D 25/06; H02S 20/30; B32B 2262/065; B32B 2262/101; B32B 2262/106; B32B 2457/12

(57) ABSTRACT

A structural composite panel is provided. The structural composite panel includes a first layer, at least one photovoltaic cell disposed on the first layer, a resin layer including the resin, and a protective layer disposed on the resin layer. The first layer includes a resin and structural reinforcement. A portion of the first layer includes the structural reinforcement encapsulated in the resin, and a portion of the first layer includes no structural reinforcement. The resin layer is disposed on the at least one photovoltaic cell.

### INTRODUCTION

The present disclosure relates to a fiber reinforced composite panel, and more particularly to a fiber reinforced composite panel having energy storage.

Photovoltaic cells, commonly known as solar cells, are widely used to convert sunlight into electrical energy. Traditionally, these cells have been installed on rooftops, solar farms, and stationary structures. However, there is a growing interest in integrating photovoltaic cells into mobile platforms, such as vehicles, to harness solar energy while on the move.

Existing approaches for integrating photovoltaic cells into vehicles have limitations. Rooftop solar panels on vehicles are often bulky, heavy, and disrupt the vehicle's aerodynamics. Additionally, visible solar panels can compromise the vehicle's aesthetics. Moreover, the life cycle of photovoltaic cells is affected by exposure to harsh environmental conditions, including temperature variations, mechanical stress, and UV radiation.

While prior art methods and systems attempt to provide structural lightweighting while including photovoltaic cells and may achieve their particular purpose, a need still exists for a new and improved solution for integrating photovoltaic cells into mobile platforms.

### SUMMARY

According to several aspects of the present disclosure, a structural composite panel is provided. The structural composite panel includes a first layer, at least one photovoltaic cell disposed on the first layer, a resin layer including the resin, and a protective layer disposed on the resin layer. The first layer includes a resin and structural reinforcement. A portion of the first layer includes the structural reinforcement encapsulated in the resin, and a portion of the first layer includes no structural reinforcement. The resin layer is disposed on the at least one photovoltaic cell.

In accordance with another aspect of the disclosure, the structural reinforcement includes fiber reinforcement.

In accordance with another aspect of the disclosure, the structural reinforcement includes at least one of carbon, glass, or basalt.

In accordance with another aspect of the disclosure, the structural reinforcement includes a reinforcing carbon fiber that carries electrical current to the at least one photovoltaic cell.

In accordance with another aspect of the disclosure, the structural reinforcement is a fiber including at least one of glass, basalt, flax, hemp, pineapple, or cellulose.

In accordance with another aspect of the disclosure, the structural reinforcement is a structural fiber that is commingled with a non-structural 3D stitch including at least one of polycarbonate, nylon, polyethylene, or polypropylene to consolidate the fiber and preform.

In accordance with another aspect of the disclosure, the at least one photovoltaic cell includes at least one of monocrystalline silicon, polycrystalline silicon, a thin film, or indium tin oxide.

In accordance with another aspect of the disclosure, the at least one photovoltaic cell is disposed on a portion of the first layer having no structural reinforcement.

In accordance with another aspect of the disclosure, the at least one photovoltaic cell is disposed on a portion of the first layer having both structural reinforcement and no structural reinforcement.

In accordance with another aspect of the disclosure, the resin includes at least one of polycarbonate or acrylic.

In accordance with another aspect of the disclosure, the protective layer is a hard coat.

In accordance with another aspect of the disclosure, the protective layer is a strengthened glass layer.

In accordance with another aspect of the disclosure, the structural composite panel is a vehicle roof panel.

According to several aspects of the present disclosure, a structural composite panel is provided. The structural composite panel includes a first layer, at least one photovoltaic cell disposed on the first layer, an optical bonding layer disposed over the at least one photovoltaic cell, and a strengthened glass layer disposed on the optical bonding layer. The first layer includes a resin and structural reinforcement. The structural reinforcement includes at least one of reinforcing carbon fiber or an insulating fiber. A portion of the first layer includes the structural reinforcement encapsulated in the resin. A portion of the first layer includes no structural reinforcement. The structural reinforcement is commingled with a non-structural 3d stitch to consolidate the at least one of the reinforcing carbon fiber or the insulating fiber. The structural composite panel is an exterior vehicle body panel.

In accordance with another aspect of the disclosure, the structural reinforcement includes a structural fiber reinforcement located around a periphery of the exterior vehicle body panel and a glass fiber structural reinforcement located in a non-periphery region. The structural fiber reinforcement is disposed in a region that connects a first region of the periphery to a second region of the periphery in a cross-car configuration.

In accordance with another aspect of the disclosure, the structural fiber reinforcement is disposed within a region outside of where a photovoltaic cell is disposed.

In accordance with another aspect of the disclosure, the at least one photovoltaic cell is encapsulated by a second resin.

In accordance with another aspect of the disclosure, the resin is a transparent resin.

In accordance with another aspect of the disclosure, the resin is at least one of thermoset or thermoplastic.

According to several aspects of the present disclosure, a method is provided. The method includes applying structural reinforcement locally to a first layer including a resin. A portion of the first layer includes the structural reinforcement encapsulated in the resin, and a portion of the first layer includes no structural reinforcement. The method also includes placing at least one photovoltaic cell on the first layer. The at least one photovoltaic cell is disposed on a portion of the first layer having no structural reinforcement. The method also includes encapsulating the photovoltaic cell and the structural reinforcement using resin infusion and placing a protective layer on the encapsulated photovoltaic cell and the resin infusion.

The above features and advantages, and other features and advantages, of the presently disclosed system and method are readily apparent from the detailed description, including the claims, and examples when taken in connection with the accompanying drawings.

### BRIEF DESCRIPTION OF THE DRAWINGS

The present disclosure will become more fully understood from the detailed description and the accompanying drawings, wherein:

FIG. 1 is a perspective view illustrating an example of a vehicle having a structural composite panel having at least one photovoltaic cell, in accordance with the present disclosure.

FIG. 2 is a side cross section view illustrating the structural composite panel shown in FIG. 1, where the structural composite panel includes a first layer, a photovoltaic cell, a resin layer, and a protective layer, in accordance with the present disclosure.

FIG. 3 is a top plan view illustrating the first layer shown in FIG. 2, where the first layer includes a resin and structural reinforcement, in accordance with the present disclosure.

FIG. 4 is a side cross section view illustrating the structural composite panel shown in FIG. 1 where the structural composite panel has a first layer, a photovoltaic cell, an optical bonding layer, and a strengthen glass layer, in accordance with the present disclosure.

FIG. 5 is a flowchart illustrating a method for forming the structural composite panel shown in FIGS. 2 and 4, in accordance with the present disclosure.

### DETAILED DESCRIPTION

Reference will now be made in detail to several examples of the disclosure that are illustrated in accompanying drawings. Whenever possible, the same or similar reference numerals are used in the drawings and the description to refer to the same or like parts or steps. The following description is merely exemplary in nature and is not intended to limit the present disclosure, application, or uses.

Photovoltaic cells are exposed to various environmental factors, including temperature fluctuations, mechanical stress, and UV radiation, especially when used in a vehicle. Traditional rooftop installations expose cells to harsh conditions, affecting their longevity. By embedding photovoltaic cells within automotive panels, they are protected from external elements, extending their life cycle and ensuring consistent energy production over the vehicle's lifespan. The composite structural panels disclosed herein provide for lightweight, aesthetically pleasing, and durable photovoltaic solutions for vehicles. By embedding photovoltaic cells directly into automotive panels including roof panels, structural lightweighting, enhanced customer satisfaction, and improved overall performance and sustainability of solar-powered vehicles is achieved.

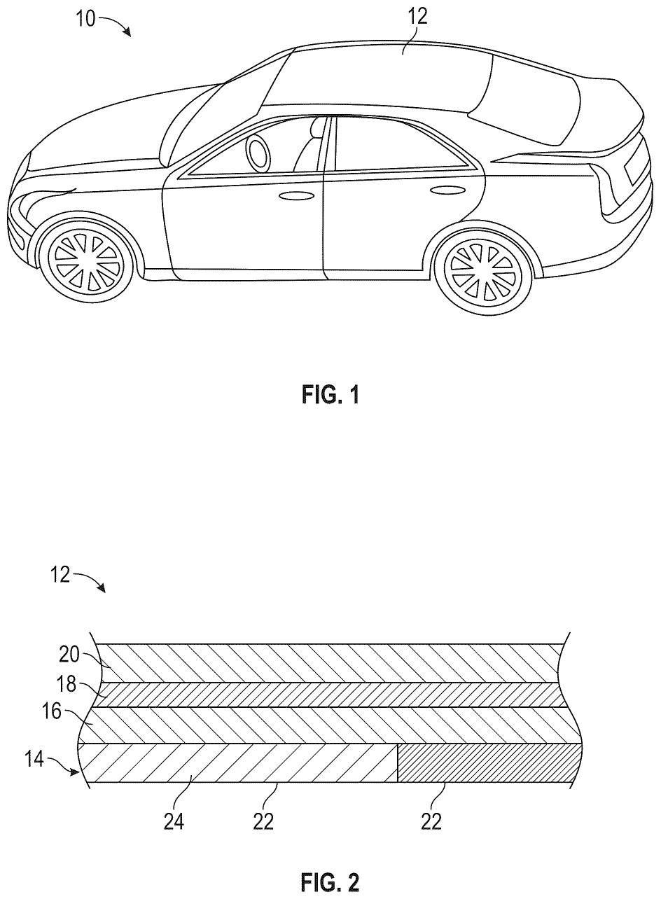

Referring to FIG. 1, a perspective view of a vehicle 10 having a structural composite panel 12 is illustrated, in accordance with the present disclosure. The structural composite panel 12 is illustrated with an exemplary vehicle 10 and is shown as a roof panel. While the vehicle 10 is illustrated as a passenger road vehicle and as a roof panel, it will be appreciated that the structural composite panel 12 may be used with various other types of vehicles and at other locations of the vehicle. For example, the structural composite panel 12 may be used in nautical vehicles, such as boats, or aeronautical vehicles, such as drones or passenger airplanes. Additionally, the structural composite panel 12 may be used in a door panel, a quarter panel, at least a portion of the hood and/or trunk, and so forth.

Referring now to FIG. 2, a side cross section view of the structural composite panel 12 is illustrated, in accordance with the present disclosure. The structural composite panel 12 includes a first layer 14, at least one photovoltaic cell 16, a resin layer 18, and a protective layer 20. As shown in FIG. 2, the first layer 14 includes resin 22 that may include, for example, a polymer. The polymer may be a thermoset polymer or a thermoplastic polymer that is substantially transparent when free of other materials (e.g., fibers). In an example, the polymer may be a thermoset polymer including at least one of benzoxazine, a bis-maleimide (BMI), a cyanate ester, an epoxy, a phenolic (PF), a polyacrylate (acrylic), a polyimide (PI), an unsaturated polyester, a polyurethane (PUR), a vinyl ester, a siloxane, co-polymers thereof, and combinations thereof. In another example, the polymer may be a thermoplastic polymer including polyethylenimine (PEI), polyamideimide (PAI), polyamide (PA) (e.g., nylon 6, nylon 66, nylon 12), polyetheretherketone (PEEK), polyetherketone (PEK), a polypheylene sulfide (PPS), a thermoplastic polyurethane (TPU), polypropylene (PP), polycarbonate/acrylonitrile butadiene styrene (PC/ABS), high-density polyethylene (HDPE), polyethylene terephthalate (PET), poly(methyl methacrylate) (PMMA), polycarbonate (PC), polyaryletherketone (PAEK), polyetherketoneketone (PEKK), copolymers thereof, and combinations thereof. In some examples, the resin 22 may include multiple polymers, and may further include an opaque polymer, for example in regions of low or no transparency.

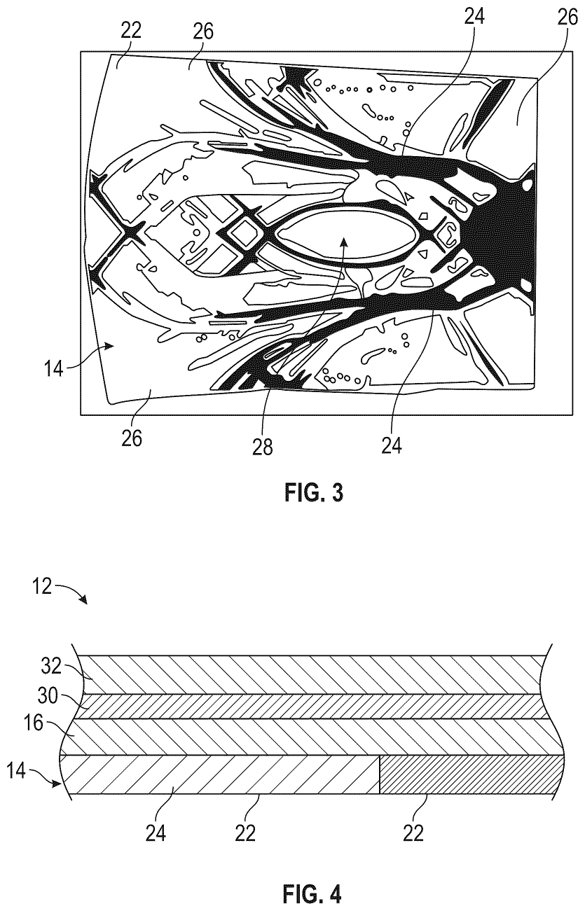

FIG. 3 is a top view illustrating the first layer 14 with structural reinforcement 24 located in a portion of the first layer 14. The structural reinforcement 24 may be disposed in all or only in portions of the first layer 14 and provides reinforcement to the structural composite panel 12. It will be appreciated that the configuration of the structural reinforcement 24 may be different than that depicted in FIG. 3, and the structural reinforcement 24 may be disposed in other locations than that depicted in FIG. 3. The structural reinforcement 24 may have lengths and/or orientations to meet a desired strength for the structural composite panel 12.

In an example, the structural reinforcement 24 may include fibers. Some examples of suitable fiber materials include carbon fibers (e.g., carbon black, carbon nanotubes, talc, fibers derived from polyacrylonitrile, pitch precursors, and the like), glass fibers (e.g., fiber glass, quartz), basalt fibers, aramid fibers (e.g., KEVLAR®, polyphenylene benzobisoxazole (PBO)), polyethylene fibers (e.g., high-strength ultra-high molecular weight (UHMW) polyethylene), polypropylene fibers (e.g., high-strength polypropylene, natural fibers (e.g., cotton, flax, hemp, cellulose, spider silk, pineapple), and combinations thereof. In an example, the structural reinforcement 24 may include reinforcing carbon fiber that carries electrical current. For example, the carbon fiber is an electrical conductor and itself can carry the electrical current. In another non-limiting example, structural reinforcement that includes the fibers may include an electrical wire (e.g., a copper wire) and/or ribbons (e.g., copper) embedded within the fiber, where the electrical wire and/or ribbons are configured to carry the electrical current.

Additionally, the structural reinforcement 24 can be a single fiber (in a dry state) or can be a commingled fiber (in a dry state) that is commingled with a non-structural 3D stitch (e.g., polycarbonate, nylon, polyethylene, polypropylene, and the like). For example, the commingled fiber may include carbon and polycarbonate (PC), carbon and polyamide 6 (PA6), carbon and polyamide 12 (PA12), glass and polycarbonate (PC), glass and polyamide 6 (PA6), and the like. The single fiber and/or the commingled fiber can be stitched, laid, or otherwise placed onto the resin 22, and in some instances, can be consolidated with the resin 22 via force and/or heat (e.g., overmolding the single fiber and/or commingled fiber with the resin 22). When an overmold layer is used, the overmold layer may be the same or similar material as the resin 22 to eliminate index of refraction mismatch issues and image distortion. Dissimilar resins may also lead to adhesion issues at an interface of the overmold layer and the resin 22.

The structural reinforcement 24 may include a combination of materials within the first layer 14. For example, the structural reinforcement 24 may include carbon fiber located around a periphery 26 of the first layer 14 and may include a glass fiber utilized in a non-periphery region 28. The periphery 26 may include an outer edge of the first layer 14. For example, the periphery 26 can include about 10% of a width W of the first layer 14. In this context, the term “about” is known to those skilled in the art. Alternatively, the term “about” may be read to mean plus or minus 1%. It will be appreciated that the periphery 26 can include other lengths or percentages of width (e.g., 5%, 15%, 20%, and so forth). When a structural reinforcement 24 (e.g., glass fiber) is disposed in the non-periphery region 28, the structural reinforcement 24 in the non-periphery region 28 can extend in a cross-car configuration or across the first layer 14 from a first portion of structural reinforcement 24 in the periphery region 26 to a second portion (or opposing region) of structural reinforcement 24 in the periphery region 26. Additionally, structural reinforcement 24 in the non-periphery region 28 extending in the cross-car configuration or across the first layer 14 from a first portion of structural reinforcement 24 in the periphery region 26 to a second portion may be disposed outside of where the photovoltaic cell 16 is located.

Referring again to FIG. 2, at least one photovoltaic cell 16 is disposed on the first layer 14. The photovoltaic cell 16 includes an electronic device that converts light energy into electricity by means of a photovoltaic effect. The at least one photovoltaic cell 16 may include, for example, monocrystalline silicon, polycrystalline silicon, cadmium telluride, a thin film, indium tin oxide, or the like. In some instances, the photovoltaic cells 16 may be opaque or substantially opaque, which provides the best energy storage. In other instances, the photovoltaic cells 16 may be transparent or substantially transparent, which provides the best visibility. In an example, and when partially transparent, each photovoltaic cell 16 may have a level of transparency including and between about 30% and 50%. In this context, the term “about” is known to those skilled in the art. Alternatively, the term “about” may be read to mean plus or minus 1%.

In some instances, the photovoltaic cell 16 is generally disposed on a portion of the first layer 14 having no structural reinforcement 24. However, it will be appreciated that the photovoltaic cell 16 may also be disposed on a portion of the first layer 14 having structural reinforcement 24. In an example, the structural composite panel 12 may include both photovoltaic cells 16 that are transparent or substantially transparent and photovoltaic cells 16 that are opaque. In this example, the photovoltaic cells 16 that are transparent or substantially transparent can be disposed at a periphery 26 where the structural reinforcement 24, the resin layer 18, and the protective layer 20 is also transparent or substantially transparent. Additionally, in this example, the photovoltaic cells 16 that are opaque can be disposed at a non-periphery region 28 where the structural reinforcement 24 is located.

As illustrated in FIG. 2, the resin layer 18 is disposed on and encapsulates the at least one photovoltaic cell 16. The resin layer 18 also can be disposed on the first layer 14 at locations where there is no photovoltaic cell 16 disposed on the first layer 14. The resin layer 18 can be a same or similar material as the resin 22 within the first layer 14. For example, the resin layer 18 can include polycarbonate or acrylic. The resin layer 18 may be transparent or at least partially transparent (e.g., translucent) and may be thermoset or thermoplastic.

As illustrated in FIG. 2, the protective layer 20 is disposed on the resin layer 18. The protective layer 20 provides UV and/or scratch protection to the structural composite panel 12. The protective layer 20 may be formed, either whole or in part, from a rigid yet transparent material. This rigid and transparent material may include a wear-resistant and scratch-resistant hard coat with a thickness ranging from several microns to about 0.1 millimeter (mm) or more. In this context, the term “about” is known to those skilled in the art. Alternatively, the term “about” may be read to mean plus or minus 0.01 mm. In some instances, the protective layer 20 may include several material layers. For example, the protective layer 20 can be a silicone hard coat with a film encased between a poly(methyl methacrylate) (PMMA) sheet and a transparent polycarbonate (PC) sheet. In another example, the protective layer can include a clear coat film that provides an optically transparent, scratch-resistant “Class A” surface. It will be appreciated that the protective layer 20 may include other similar materials than those listed.

FIG. 4 illustrates a structural composite panel 12 having a first layer 14, at least one photovoltaic cell 16 disposed on the first layer 14, an optical bonding layer 30 disposed on the at least one photovoltaic cell 16 and/or the first layer 14, and a strengthened glass layer 32 disposed on the optical bonding layer 30. The first layer 14 and/or the at least one photovoltaic cell 16 are similar to those previously described.

The optical bonding layer 30 operatively couples the at least one photovoltaic cell 16, and/or the first layer to subsequent layers (e.g., the strengthened glass layer 32) without impeding optical characteristics of the structural composite panel 12. The optical bonding layer 30 is formed from a transparent adhesive material offering, for example, having about 75-90% transparency. In this context, the term “about” is known to those skilled in the art. Alternatively, the term “about” may be read to mean plus or minus 1% transparency. The transparent adhesive material may include a thermoset ethylene-vinyl acetate (EVA) optical bonding agent or a thermoplastic polyvinyl butyral (PVB) optical bonding agent. The optical bonding layer 30 may be from about 0.01 millimeters (mm) to about 1 mm. In this context, the term “about” is known to those skilled in the art. Alternatively, the term “about” may be read to mean plus or minus 0.1 mm.

As illustrated in FIG. 4, the strengthened glass layer 32 is disposed on and coupled to the optical bonding layer 30. The strengthened glass layer 32 provides scratch and damage resistance to the structural composite panel 12. The strengthened glass layer 32 may be formed from, for example, heat-strengthened glass that includes glass heated to a temperature below its melting point and then cooled. Additionally, the strengthened glass layer 32 may be formed from, for example, a chemically strengthened glass, a tempered glass, a soda-lime glass, an alkali-aluminosilicate sheet glass, a ceramic material or a glass-ceramic, and so forth, with an individual thickness of about 0.3 mm to about 3.0 mm. In this context, the term “about” is known to those skilled in the art. Alternatively, the term “about” may be read to mean plus or minus 0.1 mm.

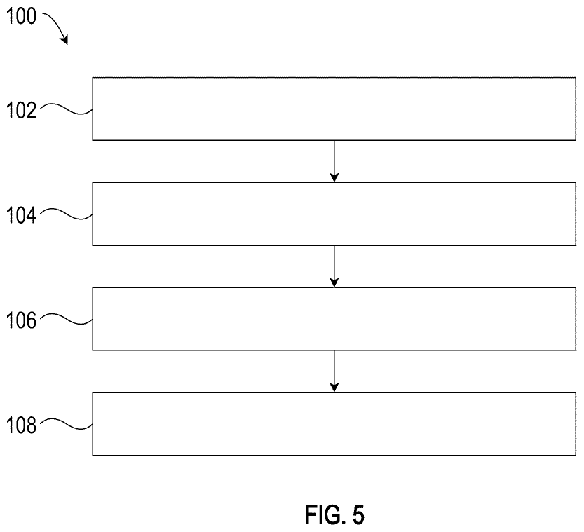

With reference to FIG. 5, a method 100 for forming the structural composite panel 12 is presented, in accordance with the present disclosure. The method starts at block 102.

Block 102 depicts applying structural reinforcement 24 locally to the first layer 14. Applying the structural reinforcement 24 may include stitching or sewing the structural reinforcement 24 (e.g., fiber) locally onto or within the resin 22 of the first layer 14. In a specific example, a needle and a roving bobbin may stitch the structural reinforcement 24 including a fiber into the resin 22 as illustrated in FIG. 3. It will be appreciated that applying the structural reinforcement 24 may include using other techniques. Method 100 then moves to block 104.

Block 104 depicts placing at least one photovoltaic cell 16 on the first layer 14. Placing the at least one photovoltaic cell 16 may include using a robot, for example, to place each photovoltaic cell 16 onto a portion of the first layer 14 that does not include the structural reinforcement 24. In some instances, placing a photovoltaic cell 16 may include locating the photovoltaic cell 16 over a portion of the first layer 14 having the structural reinforcement 24 therein. Each photovoltaic cell 16 can be incorporated onto the first layer 14 before step 106. In some instances, placing each photovoltaic cell 16 may include using a consumable “tear-away” protective layer, for example, E paper, to protect the photovoltaic cells 16 during the manufacturing steps. Method 100 then moves to block 106.

Block 106 depicts encapsulating the at least one photovoltaic cell 16 and the structural reinforcement 24 of the first layer 14 using, for example, resin infusion. Resin infusion can include placing the first layer 14 and the photovoltaic cell(s) 16 thereon, in a dry state, into a mold. A flexible membrane, for example a vacuum bag, is then sealed against edges of the mold using a tape (e.g., sealant tape). The first layer 14 and the photovoltaic cell(s) 16 are then placed under a vacuum within the mold. Atmospheric pressure drives liquid resin through the dry structural reinforcement 24 of the first layer 14 wetting the structural reinforcement 24 and photovoltaic cell(s) 16. The liquid resin permeates the structural reinforcement 24 of the first layer 14 and the photovoltaic cell(s) to form the resin layer 18. In some instances, when the optical bonding layer 30 is utilized, block 106 includes encapsulating the at least one photovoltaic cell 16 with the optical bonding layer 30. Method 100 then moves to block 108.

Block 108 depicts placing the protective layer 20 on the resin layer 18. When an optical bonding layer 30 and strengthened glass layer 32 is used, block 108 depicts placing the strengthened glass layer 32 on the optical bonding layer 30. The protective layer 20 and/or the strengthened glass layer 32 may be placed on the resin layer 18 or the optical bonding layer 30, respectively, using a robot, for example.

The structural composite panel 12 of the present disclosure is advantageous and beneficial over the prior art. Photovoltaic cells are exposed to various environmental factors, including temperature fluctuations, mechanical stress, and UV radiation. Additionally, traditional rooftop installations expose cells to harsh conditions, affecting their longevity. By embedding photovoltaic cells within automotive panels, they are protected from external elements, extending their life cycle and ensuring consistent energy production over the vehicle's lifespan. By embedding photovoltaic cells directly into automotive panels including roof panels, structural lightweighting, enhanced customer satisfaction and aesthetics, and improved overall performance and sustainability of solar-powered vehicles is achieved.

This description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

What is claimed is:

1. A structural composite panel, comprising:
a first layer including
a resin; and
structural reinforcement, wherein a portion of the first layer includes the structural reinforcement encapsulated in the resin, and a portion of the first layer includes no structural reinforcement;
at least one photovoltaic cell disposed on the first layer;
a resin layer including the resin, wherein the resin layer is disposed on the at least one photovoltaic cell; and
a protective layer disposed on the resin layer.

2. The structural composite material of claim 1, wherein the structural reinforcement includes fiber reinforcement.

3. The structural composite material of claim 1, wherein the structural reinforcement includes at least one of carbon, glass, or basalt.

4. The structural composite material of claim 1, wherein the structural reinforcement includes a reinforcing carbon fiber that carries electrical current to the at least one photovoltaic cell.

5. The structural composite material of claim 1, wherein the structural reinforcement is a fiber including at least one of glass, basalt, flax, hemp, pineapple, or cellulose.

6. The structural composite material of claim 1, wherein the structural reinforcement is a structural fiber that is commingled with a non-structural 3D stitch including at least one of polycarbonate, nylon, polyethylene, or polypropylene to consolidate the fiber and preform.

7. The structural composite material of claim 1, wherein the at least one photovoltaic cell includes at least one of monocrystalline silicon, polycrystalline silicon, a thin film, or indium tin oxide.

8. The structural composite material of claim 1, wherein the at least one photovoltaic cell is disposed on a portion of the first layer having no structural reinforcement.

9. The structural composite material of claim 1, wherein the at least one photovoltaic cell is disposed on a portion of the first layer having both structural reinforcement and no structural reinforcement.

10. The structural composite material of claim 1, wherein the resin includes at least one of polycarbonate or acrylic.

11. The structural composite material of claim 1, wherein the protective layer is a hard coat.

12. The structural composite material of claim 1, wherein the protective layer is a strengthened glass layer.

13. The structural composite material of claim 1, wherein the structural composite panel is a vehicle roof panel.

14. A structural composite panel, comprising:
a first layer including
a resin; and
a structural reinforcement including at least one of reinforcing carbon fiber or an insulating fiber, wherein a portion of the first layer includes the structural reinforcement encapsulated in the resin, and a portion of the first layer includes no structural reinforcement, and wherein the structural reinforcement is commingled with a non-structural 3d stitch to consolidate the at least one of the reinforcing carbon fiber or the insulating fiber;
at least one photovoltaic cell disposed on the first layer;
an optical bonding layer disposed over the at least one photovoltaic cell; and
a strengthened glass layer disposed on the optical bonding layer, wherein the structural composite panel is an exterior vehicle body panel.

15. The structural composite panel of claim 14, wherein the structural reinforcement includes a structural fiber reinforcement located around a periphery of the exterior vehicle body panel and a glass fiber structural reinforcement located in a non-periphery region, and wherein the structural fiber reinforcement is disposed in a region that connects a first region of the periphery to a second region of the periphery in a cross-car configuration.

16. The structural composite panel of claim 15, wherein the structural fiber reinforcement is disposed within a region outside of where a photovoltaic cell is disposed.

17. The structural composite panel of claim 14, wherein the at least one photovoltaic cell is encapsulated by a second resin.

18. The structural composite panel of claim 14, wherein the resin is a transparent resin.

19. The structural composite panel of claim 14, wherein the resin is at least one of thermoset or thermoplastic.

20. A method, comprising:
applying structural reinforcement locally to a first layer including a resin, wherein a portion of the first layer includes the structural reinforcement encapsulated in the resin, and a portion of the first layer includes no structural reinforcement;
placing at least one photovoltaic cell on the first layer, wherein the at least one photovoltaic cell is disposed on a portion of the first layer having no structural reinforcement;
encapsulating the photovoltaic cell and the structural reinforcement using resin infusion; and
placing a protective layer on the encapsulated photovoltaic cell and the resin infusion.
